(19) United States
(12) Patent Application Publication
(10) Pub. No.: US 2025/0212502 A1
(43) Pub. Date: Jun. 26, 2025

(54) SEMICONDUCTOR DEVICE AND METHOD OF MANUFACTURING THE SAME

(71) Applicant: Renesas Electronics Corporation, Tokyo (JP)

(72) Inventors: Hiroyoshi KUDOU, Tokyo (JP); Hiroshi YANAGIGAWA, Tokyo (JP); Yasutaka NAKASHIBA, Tokyo (JP)

(21) Appl. No.: 18/937,185

(22) Filed: Nov. 5, 2024

(30) Foreign Application Priority Data
Dec. 25, 2023 (JP) 2023-217922

(51) Int. Cl. H01L 27/07; H01L 21/8249; H01L 29/06; H01L 29/78; H01L 29/866

(52) U.S. Cl. CPC H10D 84/811; H10D 62/107; H10D 84/0109; H10D 84/038; H10D 8/25; H10D 30/601

(57) ABSTRACT

A semiconductor device has: a first semiconductor layer of a first conductivity type; a second semiconductor layer of a second conductivity type differing from the first conductivity type in the first semiconductor layer; a third semiconductor layer of the second conductivity type in the second semiconductor layer and having a higher impurity concentration than the second semiconductor layer; a fourth semiconductor layer of the first conductivity type on the third semiconductor layer; a fifth semiconductor layer of the first conductivity type on the fourth semiconductor layer and having a higher impurity concentration than the fourth semiconductor layer; a sixth semiconductor layer of the second conductivity type in the second semiconductor layer and having a higher impurity concentration than the third semiconductor layer; and a seventh semiconductor layer of the second conductivity type having the same impurity concentration distribution as the third semiconductor layer in a depth direction.

### CROSS-REFERENCE TO RELATED APPLICATIONS

The disclosure of Japanese Patent Application No. 2023-217922 filed on Dec. 25, 2023 including the specification, drawings and abstract is incorporated herein by reference in its entirety.

### BACKGROUND

The present invention relates to a semiconductor device and a method of manufacturing a semiconductor device, and particularly relates to a semiconductor device including a diode, and a method of manufacturing such a semiconductor device.

There are disclosed techniques listed below.
[Patent Document 1] Japanese Unexamined Patent Application Publication No. 2013-183039

Patent Document 1 describes a technique to reduce the number of manufacturing processes by simultaneously forming a cathode of a Zener diode and source and drain regions of a transistor.

### SUMMARY

When a transistor with a low impurity concentration region such as a Lightly-Doped Drain (LDD) region and a diode (for example, a Zener diode) are simultaneously formed, a problem arises in that an operating resistance of the diode increases.

Other problems and novel features will become apparent from the description of the present specification and the accompanying drawings.

According to an embodiment, there is provided a semiconductor device having: a first semiconductor layer of a first conductivity type; a second semiconductor layer of a second conductivity type provided in the first semiconductor layer, the second conductivity type differing from the first conductivity type; a third semiconductor layer provided in the second semiconductor layer and having a higher impurity concentration than the second semiconductor layer; a fourth semiconductor layer of the first conductivity type provided on the third semiconductor layer; a fifth semiconductor layer of the first conductivity type provided on the fourth semiconductor layer and having a higher impurity concentration than the fourth semiconductor layer; a sixth semiconductor layer of the second conductivity type provided in the second semiconductor layer and having a higher impurity concentration than the third semiconductor layer; and a seventh semiconductor layer of the second conductivity type having the same impurity concentration distribution as the third semiconductor layer in a depth direction and having an upper surface in contact with the sixth semiconductor layer.

According to an embodiment, there is provided a method of manufacturing a semiconductor device, including: a step of forming a second semiconductor layer of a second conductivity type in a first semiconductor layer of a first conductivity type, the second conductivity type differing from the first conductivity type; a step of forming a third semiconductor layer of the second conductivity type in the second semiconductor layer, the third semiconductor layer having a higher impurity concentration than the second semiconductor layer; a step of forming a fourth semiconductor layer of the first conductivity type on the third semiconductor layer; a step of forming a fifth semiconductor layer of the first conductivity type on the fourth semiconductor layer, the fifth semiconductor layer having a higher impurity concentration than the fourth semiconductor layer; and a step of forming a sixth semiconductor layer of the second conductivity type in the second semiconductor layer, the sixth semiconductor layer having a higher impurity concentration than the third semiconductor layer, wherein, in the step of forming the third semiconductor layer, a seventh semiconductor layer of the second conductivity type is simultaneously formed with the third semiconductor layer, the seventh semiconductor layer having an upper surface in contact with the sixth semiconductor layer, and having a higher impurity concentration than the second semiconductor layer.

According to the embodiments, it is possible to provide a semiconductor device capable of suppressing an increase in an operating resistance of a diode including a semiconductor layer with low impurity concentration, and to provide a method of manufacturing such a semiconductor device.

### BRIEF DESCRIPTION OF THE DRAWINGS

FIG. 1 is a schematic cross-sectional view of a semiconductor device according to a first comparative example.

FIG. 2 is a schematic cross-sectional view of a semiconductor device according to a second comparative example.

FIG. 3 is a graph showing impurity concentration distribution in the semiconductor device according to the first comparative example and the second comparative example.

FIG. 4 is a schematic cross-sectional view of a semiconductor device according to a first embodiment.

FIG. 5 is a graph showing electrical characteristics of the semiconductor device according to the first embodiment.

FIG. 6 is a graph showing impurity concentration distribution in the semiconductor device according to the first embodiment.

FIG. 7 is a graph showing variations in electrical characteristics of the semiconductor device according to the first embodiment.

### DETAILED DESCRIPTION

The following descriptions and drawings have been abbreviated and simplified as appropriate for clarity. In each of the drawings, identical elements are denoted by an identical reference sign, and redundant descriptions are omitted as appropriate.

### Considerations Leading to The Embodiment

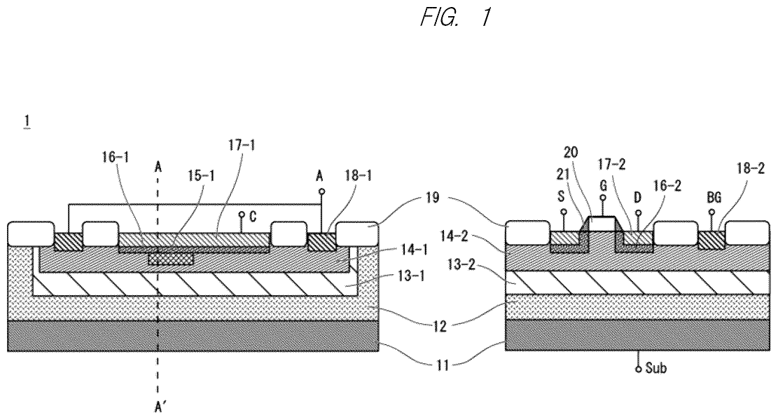

FIG. 1 is a schematic cross-sectional view of a semiconductor device 1 according to a first comparative example. The drawing on the left is a schematic cross-sectional view of a region where a Zener diode is formed (also referred to as a diode region), and the drawing on the right is a schematic cross-sectional view of a region where an N channel type transistor is formed (also referred to as a transistor region). A downward direction in FIG. 1 is also referred to as a depth direction. The semiconductor device 1 may be an Intelligent Power Device (IPD) in which a power transistor region and an element region including a diode region and a transistor region are mounted on a single semiconductor chip.

The semiconductor device 1 includes a semiconductor substrate 11, an epitaxial layer 12, a High-Voltage (HV) p well 13-1, a HV p well 13-2, a p well 14-1, a p well 14-2, a Zener diode (ZD) anode layer 15-1, an n type semiconductor layer 16-1, an n type semiconductor layer 16-2, an n+ type semiconductor layer 17-1, an n+ type semiconductor layer 17-2, a p+ type semiconductor layer 18-1, a p+ type semiconductor layer 18-2, an insulating film 19, a gate electrode 20, and a spacer 21.

The semiconductor substrate 11 is, for example, an n type semiconductor substrate. The epitaxial layer 12 is, for example, an epitaxial film formed on the semiconductor substrate 11 by an epitaxial growth method. The semiconductor substrate 11 is connected to a substrate terminal (Sub). The semiconductor substrate 11 and the epitaxial layer 12 correspond to a first semiconductor layer.

Referring to the drawing on the left, the p type HV p well 13-1 is formed in the epitaxial layer 12. The p type p well 14-1 is formed in the HV p well 13-1. The impurity concentration of the p well 14-1 is higher than the impurity concentration of the HV p well 13-1. The HV p well 13-1 and the p well 14-1 are formed by, for example, ion implantation using a patterned resist as a mask. The HV p well 13-1 and the p well 14-1 correspond to a second semiconductor layer.

The ZD anode layer 15-1 (third semiconductor layer) with p type impurities (for example, boron) is formed in the p well 14-1. The impurity concentration of the ZD anode layer 15-1 is higher than the impurity concentration of the p well 14-1. The ZD anode layer 15-1 has an upper surface in contact with a lower surface of the n type semiconductor layer 16-1. The ZD anode layer 15-1 forms an anode of the Zener diode. The ZD anode layer 15-1 is formed by, for example, ion implantation using a patterned resist as a mask.

The n type semiconductor layer 16-1 (fourth semiconductor layer) with n type impurities (for example, phosphorus) is formed on the ZD anode layer 15-1. The lower surface of the n type semiconductor layer 16-1 is in contact with the ZD anode layer 15-1 and the p well 14-1. The n type semiconductor layer 16-1 is formed by, for example, ion implantation using a patterned resist as a mask.

The n+ type semiconductor layer 17-1 (fifth semiconductor layer) with n+ type impurities (for example, arsenic, phosphorus) is formed on the n type semiconductor layer 16-1. The impurity concentration of the n+ type semiconductor layer 17-1 is higher than the impurity concentration of the n type semiconductor layer 16-1. The n type semiconductor layer 16-1 and the n+ type semiconductor layer 17-1 form a cathode of the Zener diode. The n+ type semiconductor layer 17-1 is connected to a cathode terminal (C). The n+ type semiconductor layer 17-1 is formed by, for example, ion implantation using a resist as a mask.

In addition, the p+ type semiconductor layer 18-1 (sixth semiconductor layer) is formed in the p well 14-1. The impurity concentration of the p+ type semiconductor layer 18-1 is higher than the impurity concentration of the ZD anode layer 15-1. The p+ type semiconductor layer 18-1 is connected to an anode terminal (A). The p+ type semiconductor layer 18-1 is formed by, for example, ion implantation using a resist as a mask.

The insulating film 19 is formed on the semiconductor substrate 11. The insulating film 19 insulates the n+ type semiconductor layer 17-1 from the p+ type semiconductor layer 18-1. The insulating film 19 may be formed by, for example, a LOCal Oxidation of Silicon (LOCOS) method, or a trench method.

Referring to the drawing on the right, the HV p well 13-2 is formed on the epitaxial layer 12, and the p well 14-2 (well region) is formed on the HV p well 13-2. The HV p well 13-2 in the transistor region and the HV p well 13-1 in the diode region are simultaneously formed and have the same impurity concentration distribution as each other. The p well 14-2 in the transistor region and the p well 14-1 in the diode region are simultaneously formed and have the same impurity concentration distribution as each other. The HV p well 13-2 is formed by, for example, ion implantation using a resist as a mask. The p well 14-2 is formed by, for example, ion implantation using a resist as a mask.

Two n type semiconductor layers 16-2 (LDD region) are formed in the p well 14-2, and the n+ type semiconductor layer 17-2 is formed on each n type semiconductor layer 16-2. The n type semiconductor layer 16-1 in the diode region and the n type semiconductor layer 16-2 in the transistor region are simultaneously formed and have the same impurity concentration distribution as each other. The n+ type semiconductor layer 17-1 in the diode region and the n+ type semiconductor layer 17-2 in the transistor region are simultaneously formed and have the same impurity concentration distribution as each other. One of the two n+ type semiconductor layers 17-2 is connected to a source terminal(S), and the other of the two n+ type semiconductor layers 17-2 is connected to a drain terminal (D). The n type semiconductor layer 16-2 is formed by, for example, ion implantation using the gate electrode 20 as a mask. The n+ type semiconductor layer 17-2 is formed by, for example, ion implantation using the gate electrode 20 and the spacer 21 as masks.

The gate electrode 20 is located between the two n+ type semiconductor layers 17-2 and is formed on the p well 14-2. The gate electrode 20 is formed by, for example, etching the polysilicon using a resist as a mask. The spacer 21 is formed on each side of the gate electrode 20. The spacer 21 is formed by, for example, anisotropic etching of a deposited oxide film or the like.

The p+ type semiconductor layer 18-2 is formed in the p well 14-2. The insulating film 19 insulates the n+ type semiconductor layer 17-2 from the p+ type semiconductor layer 18-2. The p+ type semiconductor layer 18-1 and the p+ type semiconductor layer 18-2 are simultaneously formed and have the same impurity concentration distribution as each other. The p+ type semiconductor layer 18-2 is connected to a back gate terminal (BG). The p+ type semiconductor layer 18-2 is formed by, for example, ion implantation using a resist as a mask.

The source and drain layers including the LDD and the cathode of the Zener diode can be simultaneously manufactured, and thus, the semiconductor device 1 according to the first comparative example can reduce the number of processes required for manufacturing.

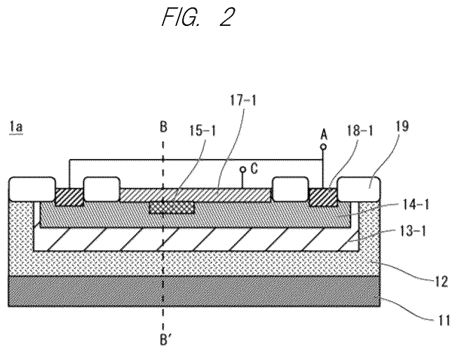

FIG. 2 is a schematic cross-sectional view of a diode region of a semiconductor device la according to a second comparative example. Note that the transistor region is omitted from the drawing. The semiconductor device la of FIG. 2 differs from the semiconductor device of FIG. 1 in that it does not include the n type semiconductor layer 16-1 (LDD).

Next, a first problem of the semiconductor device 1 according to the first comparative example will be described. The semiconductor device 1 includes the n type semiconductor layer 16-1 with low impurity concentration, and thus, a problem arises in which an operating resistance Ron of the Zener diode becomes higher than that of the second comparative example.

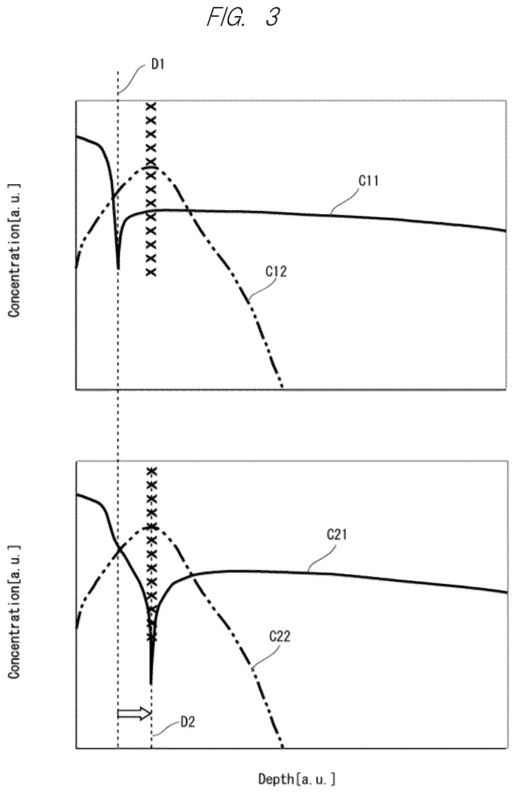

Next, a second problem of the semiconductor device 1 according to the first comparative example will be described. The upper drawing in FIG. 3 is a graph showing impurity concentration distribution along a B-B′ cross section of FIG. 2. A horizontal axis represents a depth from a surface (surface on which the Zener diode is formed). A curve C11 represents carrier concentration distribution, curve and a C12 represents concentration distribution of p type impurities injected into the ZD anode layer 15-1 immediately after injection. A dotted line D1 represents a depth position of a center of a depletion layer. Concentration distribution of p type impurities forming the ZD anode layer 15-1 is set to have a peak at a predetermined depth position. A peak position corresponds to a depth (also referred to as a range) at which ions enter from a surface of the semiconductor device la. At the peak position where impurity concentration distribution is at a maximum, point defects are formed due to ion implantation. Cross marks indicate the depth positions where point defects are formed.

The lower drawing in FIG. 3 is a graph showing carrier concentration distribution along an A-A′ cross section of FIG. 1. A curve C21 represents carrier concentration distribution, and a curve C22 represents concentration distribution of p type impurities injected into the ZD anode layer 15-1. A dotted line D2 represents a depth position of a center of a depletion layer. The presence of the n type semiconductor layer 16-1 (LDD) makes the depletion layer shift to a deeper position, as indicated by a rightward arrow. Thus, point defects are formed in the depletion layer due to ion implantation. Therefore, the semiconductor device 1 according to the first comparative example has a problem in that point defects cause an increase in leakage current of the Zener diode.

### First Embodiment

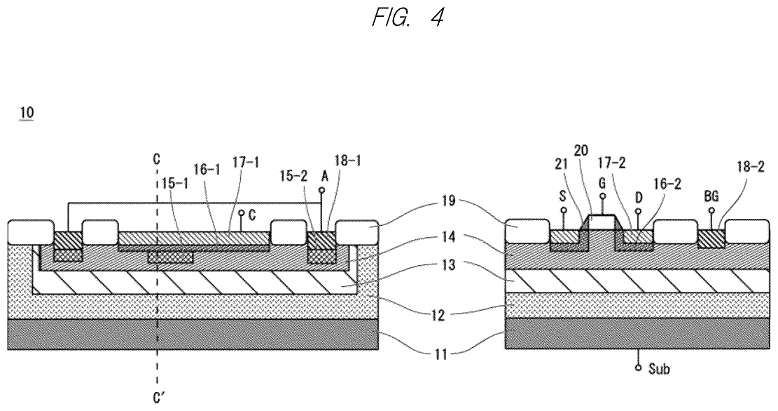

FIG. 4 is a schematic cross-sectional view of a semiconductor device 10 according to a first embodiment. The semiconductor device 10 of FIG. 3 differs from the semiconductor device of FIG. 1 in that it further includes a p type semiconductor layer 15-2 (seventh semiconductor layer) in the diode region. The p type semiconductor layer 15-2 is simultaneously formed with the ZD anode layer 15-1 and has the same impurity concentration distribution as the ZD anode layer 15-1. The p type semiconductor layer 15-2 is formed in the p well 14-1. The p type semiconductor layer 15-2 has an upper surface in contact with a lower surface of the p+ type semiconductor layer 18-1. The p type semiconductor layer 15-2 is formed by, for example, ion implantation using a resist as a mask.

The p type semiconductor layer 15-2 with a high impurity concentration is formed on a path for a current after breakdown of the Zener diode, and thus, the first embodiment can reduce the operating resistance of the Zener diode.

In addition, the HV p wells 13-1 and 13-2 are replaced by a common HV p well 13, and the p wells 14-1 and 14-2 are replaced by a common p well 14. For example, the HV p well 13 and the p well 14 may be arranged across an entire lower layer of the semiconductor chip.

In addition, the ion implantation range of p type impurities when forming the ZD anode layer 15-1 and the p type semiconductor layer 15-2 is set at a position deeper or shallower than the depletion layer formed between the anode and the cathode of the Zener diode. Note that the anode of the Zener diode is formed by the ZD anode layer 15-1, and the cathode of the Zener diode is formed by the n type semiconductor layer 16-1 and the n+ type semiconductor layer 17-1. Point defects formed when forming the ZD anode layer 15-1 are located at a position deeper or shallower than the depletion layer, and thus, the first embodiment can reduce the leakage current of the Zener diode.

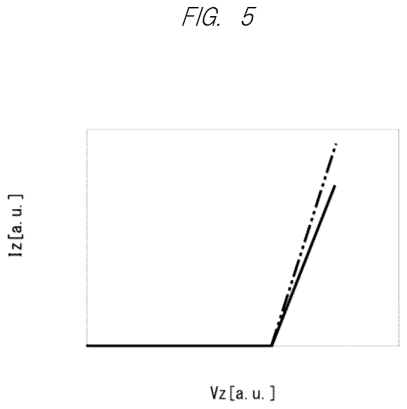

FIG. 5 is a graph showing electrical characteristics of the Zener diode according to the first embodiment. The horizontal axis represents a Zener voltage Vz [a.u.] and the vertical axis represents a Zener current Iz [a.u.]. A two-dot-dash line represents electrical characteristics of the Zener diode according to the first embodiment, and the solid line represents electrical characteristics of the Zener diode according to the second comparative example. It was found that the first embodiment can reduce the operating resistance of the Zener diode according to the second comparative example by approximately 24%.

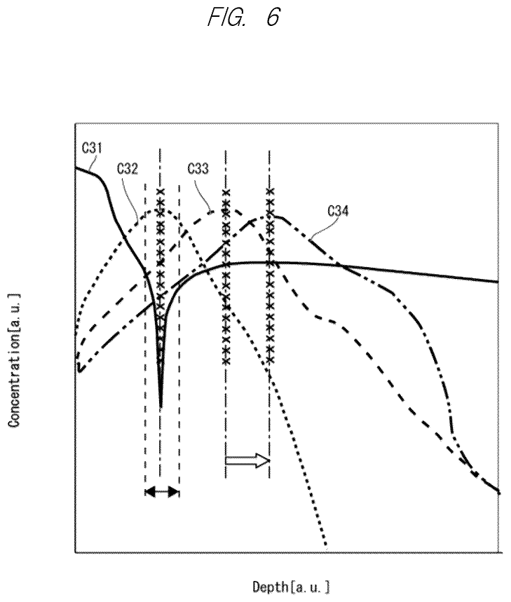

Referring to FIG. 6, a curve C31 represents carrier concentration distribution along a C-C′ cross section of FIG. 4. The two-headed arrow represents a range of the depletion layer in a pn junction.

A curve C32 represents impurity concentration distribution when an acceleration voltage of ions is 70 keV. A curve C33 represents impurity concentration distribution when the acceleration voltage of ions is 150 keV. A curve C34 represents impurity concentration distribution when the acceleration voltage of ions is 180 keV. When the acceleration voltage of ions is 70 kev, point defects formed due to ion implantation are located in the depletion layer, causing the leakage current to increase. Setting the acceleration voltage of ions to 150 keV allows point defects to be formed at a position deeper than the depletion layer, and thus, it is possible to suppress the increase in the leakage current. In addition, setting the acceleration voltage of ions to 180 keV allows point defects to be formed at an even deeper position, as shown by a rightward arrow. Note that the increase in the leakage current can be suppressed by setting the acceleration voltage to be even smaller and setting the ion implantation range at a position shallower than the depletion layer.

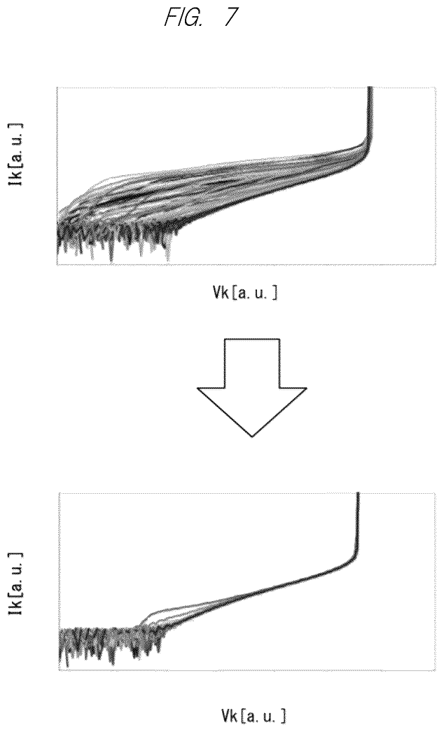

The upper drawing in FIG. 7 is a graph showing variations in electrical characteristics of the Zener diode when the acceleration voltage of ions is 70 keV, and the lower drawing in graph variations in electrical FIG. 7 is a showing characteristics of the Zener diode when the acceleration voltage of ions is 150 keV. The vertical axis of the graph represents a current value Ik [a.u.], and the horizontal axis represents a voltage value Vk [a.u.]. Setting the acceleration voltage of ions to 150 keV makes it possible to suppress variations in electrical characteristics and improve the yield.

The first embodiment can reduce the operating resistance of the diode. In addition, the first embodiment can reduce the leakage current flowing in the diode.

In the foregoing, the invention made by the present inventor has been described in detail based on the embodiments. However, it goes without saying that the present invention is not limited to the above-described embodiments, and can be changed in various ways without departing from the gist of the invention.

For example, an IGBT according to the above-described embodiment may have a configuration in which conductivity types (p type or n type) of a semiconductor substrate, semiconductor layer, diffusion layer or the like are inverted. For example, one of the n type and p type conductivity type can be a first conductivity type and the other conductivity type can be a second conductivity type. In such a case, the first conductivity type can be the p type, and the second conductivity type can be the n type, or conversely, the first conductivity type can be the n type and the second conductivity type can be the p type.

What is claimed is:

1. A semiconductor device comprising:
a first semiconductor layer of a first conductivity type;
a second semiconductor layer of a second conductivity type provided in the first semiconductor layer, the second conductivity type differing from the first conductivity type;
a third semiconductor layer provided in the second semiconductor layer and having a higher impurity concentration than the second semiconductor layer;
a fourth semiconductor layer of the first conductivity type provided on the third semiconductor layer;
a fifth semiconductor layer of the first conductivity type provided on the fourth semiconductor layer and having a higher impurity concentration than the fourth semiconductor layer;
a sixth semiconductor layer of the second conductivity type provided in the second semiconductor layer and having a higher impurity concentration than the third semiconductor layer; and
a seventh semiconductor layer of the second conductivity type having the same impurity concentration distribution as the third semiconductor layer in a depth direction and having an upper surface in contact with the sixth semiconductor layer.

2. The semiconductor device according to claim 1,
wherein a depletion layer is formed between one of an anode and a cathode formed by the third semiconductor layer and the other of the anode and the cathode formed by the fourth semiconductor layer and the fifth semiconductor layer, and
wherein point defects formed when ions of impurities of the second conductivity type are implanted in the third semiconductor layer are located at a position deeper or shallower than the depletion layer.

3. The semiconductor device according to claim 2, further comprising a transistor provided in the second semiconductor layer, the transistor having a Lightly-Doped Drain (LDD) region of the first conductivity type having the same impurity concentration distribution as the fourth semiconductor layer in the depth direction.

4. The semiconductor device according to claim 3,
wherein the third semiconductor layer forms the anode of a Zener diode, and the fifth semiconductor layer and the sixth semiconductor layer form the cathode of the Zener diode.

5. The semiconductor device according to claim 4,
wherein the semiconductor device is an Intelligent Power Device (IPD) in which the Zener diode and the transistor are mounted on a single semiconductor chip.

6. A method of manufacturing a semiconductor device including:
a step of forming a second semiconductor layer of a second conductivity type in a first semiconductor layer of a first conductivity type, the second conductivity type differing from the first conductivity type;
a step of forming a third semiconductor layer of the second conductivity type in the second semiconductor layer, the third semiconductor layer having a higher impurity concentration than the second semiconductor layer;
a step of forming a fourth semiconductor layer of the first conductivity type on the third semiconductor layer;
a step of forming a fifth semiconductor layer of the first conductivity type on the fourth semiconductor layer, the fifth semiconductor layer having a higher impurity concentration than the fourth semiconductor layer; and
a step of forming a sixth semiconductor layer of the second conductivity type in the second semiconductor layer, the sixth semiconductor layer having a higher impurity concentration than the third semiconductor layer,
wherein, in the step of forming the third semiconductor layer, a seventh semiconductor layer of the second conductivity type is simultaneously formed with the third semiconductor layer, the seventh semiconductor layer having an upper surface in contact with the sixth semiconductor layer, and having a higher impurity concentration than the second semiconductor layer.

7. The method of manufacturing a semiconductor device according to claim 6,
wherein a depletion layer is formed between one of an anode and a cathode formed by the third semiconductor layer and the other of the anode and the cathode formed by the fourth semiconductor layer and the fifth semiconductor layer, and
wherein a range of ions of impurities of the second conductive type implanted in the step of forming the third semiconductor layer is set at a position deeper or shallower than the depletion layer.

8. The method of manufacturing a semiconductor device according to claim 7,
wherein, in the step of forming the fourth semiconductor layer, a Lightly-Doped Drain (LDD) region of the first conductivity type is formed in the second semiconductor layer simultaneously with the fourth semiconductor layer.

9. The method of manufacturing a semiconductor device according to claim 8,
wherein the third semiconductor layer forms the anode of a Zener diode, and the third semiconductor layer and the fifth semiconductor layer form the cathode of the Zener diode.
